(19) United States
(12) Patent Application Publication
(10) Pub. No.: US 2006/0110095 A1
(43) Pub. Date: May 25, 2006

(54) Optical chip for optical transmission and method of making the same

(75) Inventor: Akio Maeda, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/052,786

(22) Filed: Feb. 9, 2005

(30) Foreign Application Priority Data
Nov. 19, 2004 (JP) 2004-336706

(51) Int. Cl. G02B 6/12; G02B 6/32; H01L 21/00

(52) U.S. Cl. 385/14; 385/31; 385/33; 385/50; 438/31; 438/33

(57) ABSTRACT

An optical chip has a substrate made of a dielectric crystal. Surfaces are defined on the substrate along parallel planes perpendicular to a flat surface of the substrate. A light waveguide is formed in the substrate along the flat surface of the substrate based on diffusion of a mineral material. A depression is formed on the flat surface of the substrate so as to locate the tip end of the light waveguide at a position retreating from the plane. The depression of the substrate can easily be formed based on etching process, for example. A flat surface can be established at the tip end of the light waveguide based on the etching process. Loss of light can be prevented to the uttermost at the contact with fiber optics connected to the light waveguide.

### BACKGROUND OF THE INVENTION

1. Field of the Invention

The present invention relates to a method of making an optical chip for optical transmission utilized to a light transmitting/receiving apparatus such as an optical modulator, for example.

2. Description of the Prior Art

As disclosed in Japanese Patent Application Publication No. 2002-22993, an optical chip for optical transmission comprises a light waveguide. A light waveguide made of resin is formed on a wafer in the production process of the optical chip. A clad layer and a protection layer cover over the wafer and the light waveguide. The light waveguide and the clad layer are thereafter cut out into a predetermined shape on the wafer based on dicing process. The tip end of the light waveguide gets exposed at a cutting plane. The wafer is then cut and divided.

The tip end of the light waveguide is exposed at the cutting plane. Scratches are often formed over the cutting plane based on scrape against a dicing blade, for example. The scratches in the tip end of the light waveguide induces loss of light on diffusion of light. Grinding or polishing process may be carried out on the cutting plane to eliminate the scratches. However, if the size of the grinding grains are minimized to accomplish the elimination of the scratches, a larger amount of time is required to complete the grinding process. The productivity gets deteriorated.

### SUMMARY OF THE INVENTION

It is accordingly an object of the present invention to provide an optical chip for optical transmission capable of easily establishing a severe flat surface at the tip end of a light waveguide.

According to a first aspect of the present invention, there is provided an optical chip comprising: a substrate made of a dielectric crystal and defining surfaces along parallel planes perpendicular to a flat surface of the substrate; a light waveguide formed in the substrate along the flat surface of the substrate based on diffusion of a mineral material; and a depression formed on the flat surface of the substrate so as to locate the tip end of the light waveguide at a position retreating from the plane.

The depression of the substrate can easily be formed based on etching process, for example. A flat surface can be established at the tip end of the light waveguide based on the etching process. Loss of light can be prevented to the uttermost at the contact with fiber optics connected to the light waveguide, for example. The depression may include a groove extending from the plane, for example.

According to a second aspect of the present invention, there is provided a method of making an optical chip, comprising: preparing a wafer made of a dielectric crystal; diffusing a mineral material from a flat surface of the wafer so as to form a light waveguide extending in the wafer along the flat surface of the wafer; and subjecting the surface of the wafer to etching process so as to form a surface along a reference plane perpendicular to the light waveguide.

The method enables cuts along the reference plane perpendicular to the light waveguide based on etching process. The tip end of the light waveguide gets exposed at the flat surface within the reference plane. A smooth surface can easily be established at the tip end of the light waveguide.

The method may further include: forming a groove crossing the light waveguide on the flat surface of the wafer so as to form the surface; and cutting the wafer along an imaginary plane in a space defined between tip ends of the light waveguides opposed to each other in the groove.

The method enables prevention of a contact between a dicing blade and the light waveguide, for example. Generation of cracks or scratches can reliably be prevented at the tip end of the light waveguide. In addition, the process can be effected in a shorter period. The working period can be shortened.

### BRIEF DESCRIPTION OF THE DRAWINGS

The above and other objects, features and advantages of the present invention will become apparent from the following description of the preferred embodiments in conjunction with the accompanying drawings, wherein:

FIG. 1 schematically illustrates the structure of an optical modulator according to a first embodiment of the present invention;

FIG. 2 is an enlarged partial perspective view schematically illustrating the structure of an optical chip for optical transmission as a specific example according to the present invention;

FIG. 3 is a plan view-schematically illustrates the structure of the optical;

FIG. 4 is a sectional view taken along the line 4-4 in FIG. 3;

FIG. 5 is a plan view schematically illustrating a wafer utilized in a method of making the optical chip;

FIG. 6 is an enlarged sectional view taken along the line 6-6 in FIG. 5, for schematically illustrating photoresist films in a pattern on the wafer;

FIG. 7 is a plan view of the wafer for schematically illustrating the process of forming a light waveguide;

FIG. 8 is an enlarged partial sectional view of the wafer for schematically illustrating wet etching process subjected to a Ti layer;

FIG. 9 is an enlarged partial sectional view of the wafer for schematically illustrating diffusion of Ti atoms;

FIG. 10 is a plan view of the wafer for schematically illustrating patterned voids in a photoresist;

FIG. 11 is an enlarged partial perspective view of the wafer for schematically illustrating a groove defined in the photoresist;

FIG. 12 is an enlarged partial perspective view of the wafer for schematically illustrating a groove defined in the wafer;

FIG. 13 is an enlarged partial sectional view of the wafer for schematically illustrating patterned voids in a photoresist;

FIG. 14 is an enlarged partial sectional view of the wafer for schematically illustrating grooves formed in a first Au layer and a Ti layer;

FIG. 15 is an enlarged partial sectional view of the wafer for schematically illustrating a second Au layer formed around a photoresist;

FIG. 16 is an enlarged partial sectional view of the wafer for schematically illustrating a third Au layer formed around a photoresist;

FIG. 17 is an enlarged partial sectional view of the wafer for schematically illustrating a photoresist filled in grooves formed through the first to third Au layer and the Ti layer;

FIG. 18 is an enlarged partial sectional view of the wafer for schematically illustrating a signal electrode and ground electrodes;

FIG. 19 is a plan view of the wafer for schematically illustrating cuts along parallel imaginary planes in parallel with the light waveguides;

FIG. 20 is a plan view of the wafer for schematically illustrating cuts along a pair of parallel imaginary plane in the direction perpendicular to the light waveguides;

FIG. 21 is an enlarged perspective view for schematically illustrating the end surface of the optical chip;

FIG. 22 schematically illustrates the structure of an optical modulator according to a second embodiment of the present invention;

FIG. 23 is an enlarged partial perspective view of the optical chip for schematically illustrating attachment of fiber optics within a depression;

FIG. 24 is an enlarged partial perspective view of an optical chip for schematically illustrating a modified example of the present invention; and

FIG. 25 is an enlarged partial perspective view of an optical chip for schematically illustrates another modified example of the present invention.

### DESCRIPTION OF THE PREFERRED EMBODIMENTS

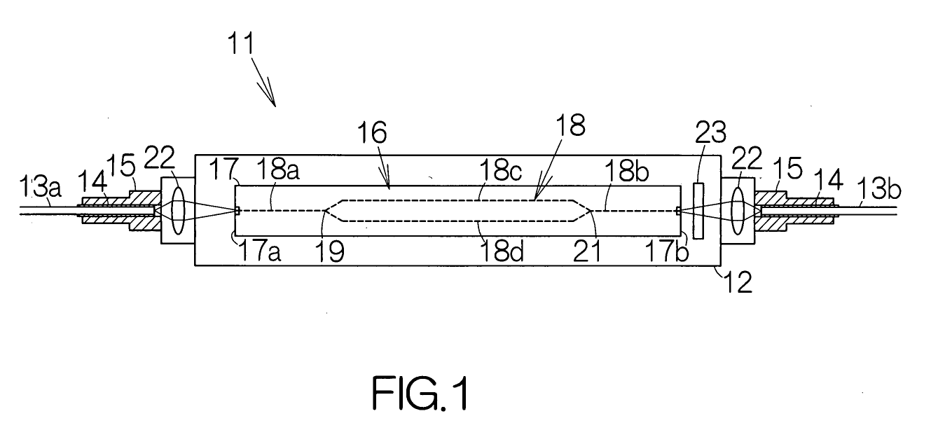

FIG. 1 schematically illustrates the structure of a light transmitting/receiving apparatus or optical modulator 11 according to a first embodiment of the present invention. The optical modulator 11 is a so-called Mach-Zehnder type modulator, for example. The optical modulator 11 includes a casing 12. Input fiber optics 13a and output fiber optics 13b are inserted into the casing 12. A ferrule 14 is attached to the individual tip ends of the fiber optics 13a, 13b so as to assist the insertion of the input and output fiber optics 13a, 13b. The ferrule 14 may be made from a glass material, for example. The ferrules 14 are removably coupled to corresponding connecters 15. The fiber optics 13a, 13b are aligned on a common straight line. As conventionally known, the individual fiber optics 13a, 13b include a core, a clad layer designed to surround the core, and a cover layer designed to cover the clad layer.

The casing 12 contains an optical chip 16 for optical transmission. The optical chip 16 is located between the fiber optics 13a, 13b. The optical chip 16 includes a body 17, a light waveguide 18 formed along the flat surface of the body 17. The body 17 is shaped in a flat plate, for example. The body 17 defines a pair of end surface 17a, 17b extending within planes perpendicular to the flat surface of the body 17. The light waveguide 18 is designed to extend in the longitudinal direction of the body 17 between the end surfaces 17a, 17b. The light waveguide 18 is allowed to transmit light through the body 17.

The tip ends of the light waveguide 18 are connected to the fiber optics 13a, 13b. The centroid of the light waveguide 18 is aligned on the longitudinal axes of the fiber optics 13a, 13b. The light waveguide 18 includes an input path 18a and an output path 18b both defined on a common straight line. The input and output paths 18a, 18b are connected to each other through first and second bifurcations 18c, 18d. The bifurcations 18c, 18d are bifurcated at divarications 19, 21 from the input and output paths 18a, 18b. The first and second bifurcations 18c, 18d may extend in parallel with each other.

A lens 22 is incorporated between the fiber optics 13a and the end surface 17a of the chip 16 and between the end surface 17b of the chip 16 and the fiber optics 13b. The lens 22 serves to condense light from the tip end of the fiber optics 13a on the tip end of the light waveguide 18. Likewise, the lens 22 serves to condense light from the tip end of the light waveguide 18 to the tip end of the fiber optics 13b.

A photodiode 23 is optionally located between the end surface 17b of the body 17 and the lens 22. The photodiode 23 serves to transform the light from the tip end of the light waveguide 18 to an electric signal. The condition of the light from the light waveguide 18 can be monitored based on the electric signal.

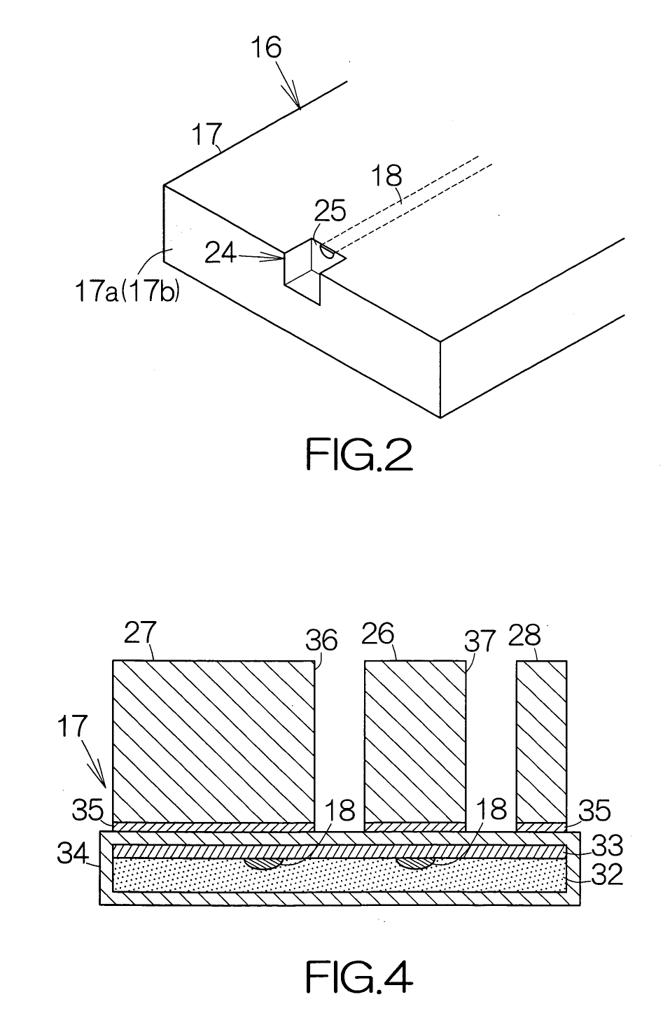

As shown in FIG. 2, depressions 24, 24 are formed on the flat surface of the body 17. The depressions 24 serve to locate the tip ends of the input and output paths 18a, 18b at positions retreating from the end surfaces 17a, 17b. The depression 24 may be a groove extending from the individual end surface 17a, 17b. Here, the tip ends of the light waveguide 18 are located on flat surfaces 25 perpendicular to the flat surface of the body 17.

As shown in FIG. 3, a signal electrode 26 is formed on the flat surface of the body 17. The signal electrode 26 is designed to extend on the first bifurcation 18c. First and second ground electrodes 27, 28 are likewise formed on the flat surface of the body 17 at locations spaced from each other. The signal electrode 26 is located in a space between the first and second ground electrodes 26, 27. The first ground electrode 27 is designed to extend on the second bifurcation 18d. One ends of these electrodes 26, 27, 28 are connected to a signal source 29. The other ends of the electrodes 26, 27, 28 are connected to a terminator 31. The signal source 29 supplies an electric signal to the signal electrode 26.

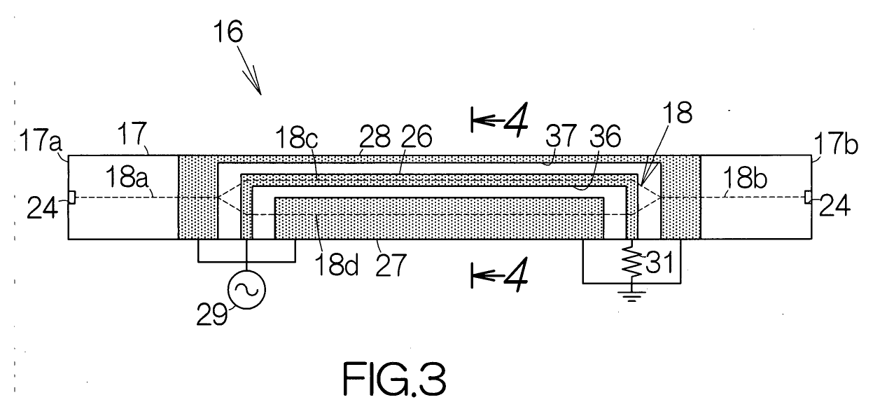

As shown in FIG. 4, the body 17 of the optical chip 16 includes a substrate 32. The substrate 32 is made of a dielectric crystal, such as LiNbO₃, for example. The substrate 32 is designed to extend along a predetermined plane. The aforementioned light waveguide 18 is formed in the substrate 32. The light waveguide 18 is formed in the substrate 32 along the flat surface of the substrate 32 based on a thermal diffusion of a mineral material, such as Ti, for example.

The body 17 includes a SiO₂ layer 33 extending over the flat surface of the substrate 32. The light waveguide 18 is thus interposed between the SiO₂ layer 33 and the substrate 32. The SiO₂ layer 33 functions as a buffer layer. The body 17 further includes a Si layer 34 extending over the surface of the SiO₂ layer 33. The Si layer 34 is designed to simultaneously cover the side and back surfaces of the substrate 32. The Si layer 34 receives the aforementioned signal electrode 26 and the first and second ground electrodes 27, 28 at its flat surface. The electrodes 26, 27, 28 may be made of an electrically conductive material, such as Au, for example. A Ti layer 35 is interposed between the electrodes 26, 27, 28 and the Si layer 34.

A predetermined space 36 is defined between the first ground electrode 27 and the signal electrode 26. Likewise, a predetermined space 37 is defined between the signal electrode 26 and the second ground electrode 28. The second ground electrode 28 is thus spaced from the signal electrode 26 at a predetermined distance. As is apparent from FIG. 3, the ends of the spaces 36, 37 reach the side surface of the body 17 extending in parallel with the light waveguide 18.

Next, a brief description will be made on the operation of the optical modulator 11. When light from the light source is inputted in the casing 12 through the input fiber optics 13a, the input light is condensed at the lens 22 so as to reach the tip end of the light waveguide 18 or input path 18a. Subsequently, the input light divaricates at the divarication 19 to the first and second bifurcations 18c, 18d. The input light is substantially divided into halves at the divarication 19. The divided light is introduced into the first and second bifurcations 18c, 18d.

On the other hand, an electric signal is inputted to the signal electrode 26 from the signal source 29. An electric field is effected on the first bifurcation 18c based on the electric signal. The refractive index of the inputted light thus changes in the first bifurcation 18c. So-called electrooptic effect serves to induce a shift of phase between the first and second bifurcations 18c, 18d. The shift of phase corresponds to values “1” and “0” of the electric signal. The light guided through the first and second bifurcations 18c, 18d is combined at the divarication 21.

The difference in the phase causes bifurcation of the combined light at the divarication 21. The light is divided into an output light led to the output path 18b and a leaked light permeating into the substrate 32 of the body 17. The output light from the tip end of the output path 18b is irradiated into the output fiber optics 13b through the lens 22. The output fiber optics 13b serve to transmit the output light or light signal toward a target destination. Information data can be read out based on the intensity of the output light at the target destination.

The aforementioned optical modulator 11 allows the tip end of the light waveguide 18 to get exposed at the position retreating from the end surface 17a, 17b in the depression 24. The depression 24 can easily be formed based on etching process, for example, as described later in detail. A smooth surface can be established at the tip end of the light waveguide 18 based on the etching process. Loss of light is prevented to the uttermost at the contact with the fiber optics 13a, 13b.

Next, description will be made on a method of making the optical chip 16 in detail. As shown in FIG. 5, a wafer 41 is first prepared. The wafer 41 is made of a dielectric crystal, such as LiNbO₃, for example. The wafer 41 corresponds to the substrate 32 of the body 17.

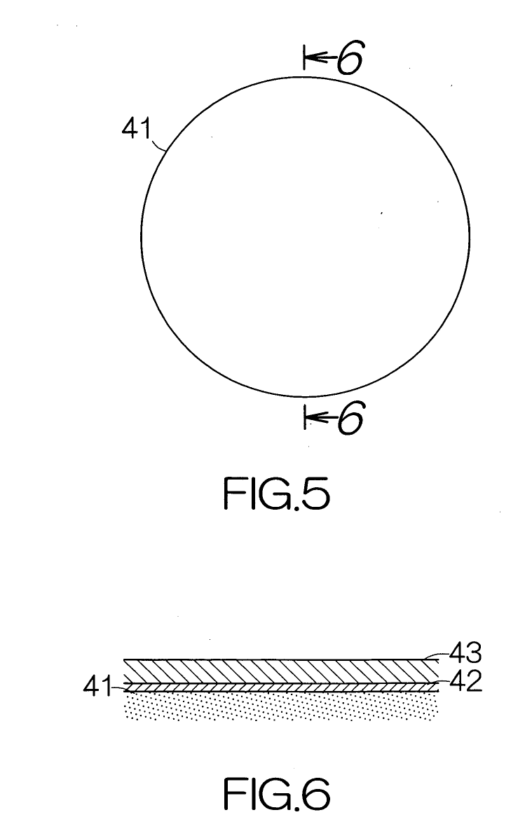

As shown in FIG. 6, a mineral material layer or Ti layer 42 is formed all over the front flat surface of the wafer 41. The wafer 41 is placed in a chamber of an evaporation apparatus, not shown. The purity of Ti is set at 4N. The vacuum is set at 6.6×10⁻⁴ [Pa] approximately in the chamber, for example. The thickness of the Ti layer 42 is set at 100 nm approximately, for example. The wafer 41 is taken out from the chamber after the establishment of the Ti layer 42.

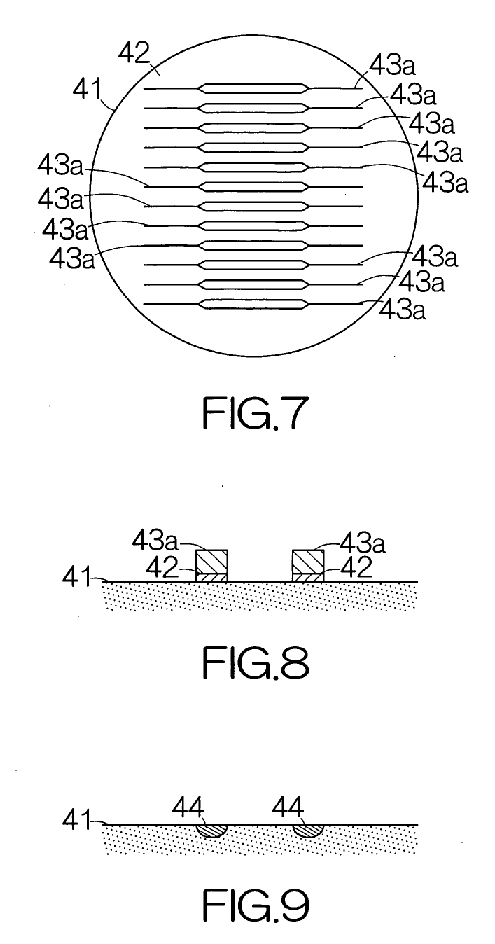

A photoresist 43 is applied to the entire surface of the Ti layer 42. The thickness of the photoresist 43 is set at 1 μm approximately, for example. The photoresist 43 is subjected to exposure and development under a proper masking. As a result, photoresist films 43a are formed in a predetermined pattern, as shown in FIG. 7. The individual photoresist film 43a is designed to reflect the pattern of the light waveguide 18. Specifically, the photoresist film 43a includes portions extending on a common straight line at locations spaced from each other, and a pair of portion extending on parallel straight lines between the portions on the common straight line. The portions on the parallel straight lines bifurcate at the inner ends of the portions on the straight line so as to connect the inner ends to each other. The surface of the Ti layer 42 is exposed around the photoresist films 43a.

Wet etching process is thereafter effected on the Ti layer 42. The Ti layer 42 is removed around the photoresist films 43a. As shown in FIG. 8, the Ti layer 42 thus remains on the surface of the wafer 41 in the predetermined pattern. The photoresist films 43a are then removed from the surface of the wafer 41.

The wafer 41 is then placed in a chamber of a diffusion apparatus, not shown. The wafer 41 is heated at 1,000 degrees Celsius in ten hours in the chamber. A pure oxygen gas circulates through the chamber at ten liter per minute. As shown in FIG. 9, Ti atoms thus diffuse into the front flat surface of the wafer 41. Light waveguides 44 are in this manner formed to extend in the wafer 41 along the front flat surface of the wafer 41 based on the diffusion of the Ti atoms. The wafer 41 is then taken out from the chamber.

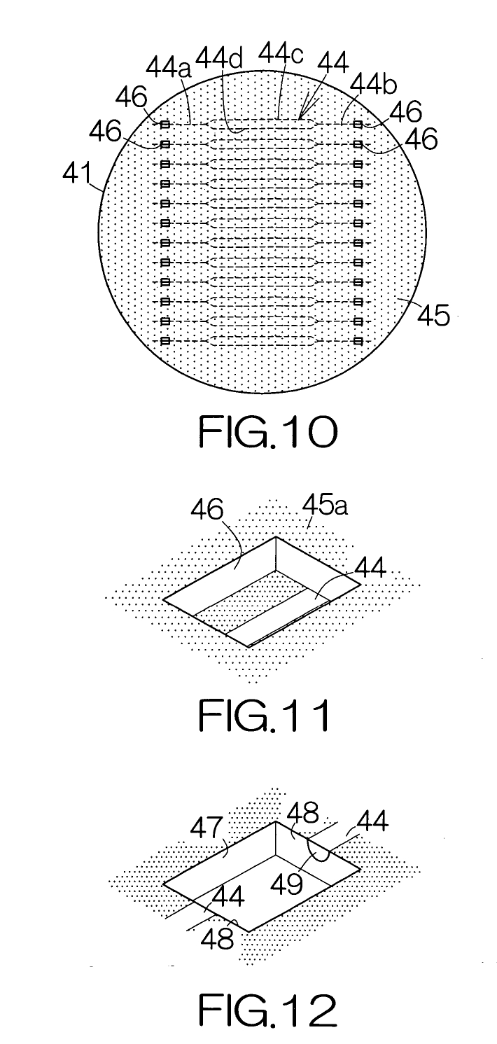

As shown in FIG. 10, the light waveguide 44 includes a pair of straight line portion 44a, 44b extending on a straight line at locations spaced from each other. A pair of parallel bifurcated straight line portions 44c, 44d are bifurcated from the inner ends of the straight line portions 44a, 44b. The bifurcated straight line portions 44c, 44d thus connect the inner ends of the straight line portions 44a, 44b to each other.

A photoresist 45 is then applied to the entire surface of the wafer 41. The thickness of the photoresist 45 is set at 15 μm approximately, for example. The photoresist 45 is subjected to exposure and development. As a result, patterned voids 46 are formed in a photoresist film 45a. As is apparent from FIG. 10, the void 46 is designed to cross the straight line portions 44a, 44b of the light waveguide 44. The surface of the wafer 41 is exposed at the bottom of the patterned voids 46.

Dry etching process is then effected on the wafer 41. Here, reactive ion etching (RIE) is carried out. The wafer 41 is placed in a chamber of a dry etching apparatus, not shown. A mixed gas of Ar gas and C₃F₈ gas is utilized as a reactive gas, for example. An antenna output of a high frequency power source is set at 1,200 W. A biasing output of a biasing power source is set at 200 W. A pressure is set at 0.25[Pa] in the chamber. The temperature is set at −10 degrees Celsius approximately in a chiller. The etching process is effected in one to three hours.

Ions collide against the surface of the photoresist 45 based on the plasma of the reactive gas in the chamber. At the same time, a chemical reaction occurs on the surface of the wafer 41 based on the reactive gas. In this manner, the material of the wafer 41 is removed in the patterned voids 46. The wafer 41 is then taken out from the chamber. The photoresist film 45a is thereafter removed from the surface of the wafer 41. A groove 47 is thus formed on the front flat surface of the wafer 41 within the patterned voids 46, as shown in FIG. 12. The grooves 47 are designed to cross the light waveguide 44 at the straight line portions 44a, 44b. Flat surfaces 48, 48 are defined in the groove 47 along reference planes perpendicular to the light waveguide 44. An end surface 49 is thus cut out at the tip end of the light waveguide 44 along the flat surface 48.

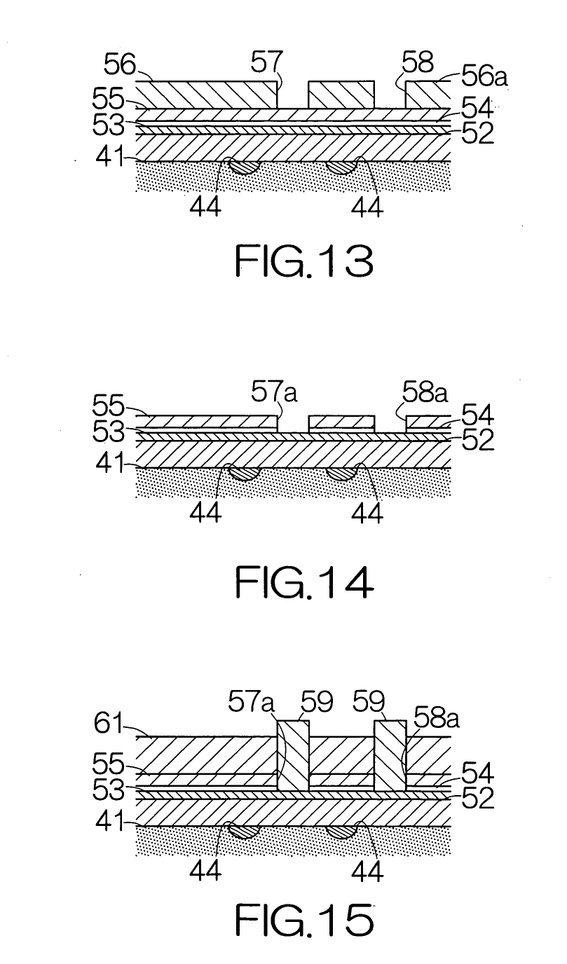

As shown in FIG. 13, a SiO₂ layer 52 is then formed on the surface of the wafer 41. The wafer 41 is placed in a chamber of a sputtering apparatus, not shown. The thickness of the SiO₂ layer 52 may be set at 1 μm approximately, for example. The wafer 41 is thereafter taken out from the chamber. The wafer 41 is subsequently heated at 600 degrees Celsius in ten hours in a chamber. A pure oxygen gas circulates through the chamber at ten liter per minute

A Si layer 53 is subsequently formed on the surface of the SiO₂ layer 52 and the back surface of the wafer 41. The wafer 41 is placed in a chamber of an evaporation apparatus, not shown. The vacuum is set at 1 [Pa] approximately in the chamber, for example. The thickness of the Si layer 53 is set at 100 nm approximately, for example. The wafer 41 is then taken out from the chamber after the establishment of the Si layer 53.

A Ti layer 54 and a first Au layer 55 are subsequently formed on the surface of the Si layer 53 in this sequence. The wafer 41 is placed in a chamber of an evaporation apparatus, not shown. The vacuum is set at 6.6×10⁻⁴[Pa] approximately in the chamber, for example. The purity of Ti is set at 4N. The thickness of the Ti layer 54 is set at 50 nm approximately, for example. The purity of Au is set equal to or larger than 4N. The thickness of the first Au layer 55 is set at 200 nm approximately, for example. The wafer 41 is then taken out from the chamber.

A photoresist 56 is subsequently applied to the entire surface of the first Au layer 55. The thickness of the photoresist 56 is set at 1 μm approximately, for example. The photoresist 56 is subjected to exposure and development. As a result, patterned voids 57, 58 are formed in a predetermined pattern in the photoresist film 56. The contour of the void 57 corresponds to the contour of the aforementioned space 36. Likewise, the contour of the void 58 corresponds to the contour of the aforementioned space 37.

The first Au layer 55 and the Ti layer 54 are subsequently subjected to wet etching process. The Au layer 55 and the Ti layer 54 are removed in the voids 57, 58. Grooves 57a, 58a are formed in the Au layer 55 and the Ti layer 54. The photoresist 55 is thereafter removed. As shown in FIG. 14, the surface of the Si layer 53 gets exposed within the grooves 57a, 58a. The first Au layer 55 and the Ti layer 54 contour the shape of the aforementioned spaces 36, 37.

A photoresist is subsequently applied to the entire surface of the wafer 41. The thickness of the photoresist is set at 13 μm approximately, for example. The photoresist is subjected to exposure and development. As a result, the photoresist films 59 are formed in a predetermined pattern, as shown in FIG. 15. The photoresist films 59 stand in the grooves 57a, 58a. A second Au layer 61 is then formed around the photoresist films 59 based on plating process. The thickness of the second Au layer 61 is set at 4 μm approximately, for example. The photoresist films 59 is thereafter removed.

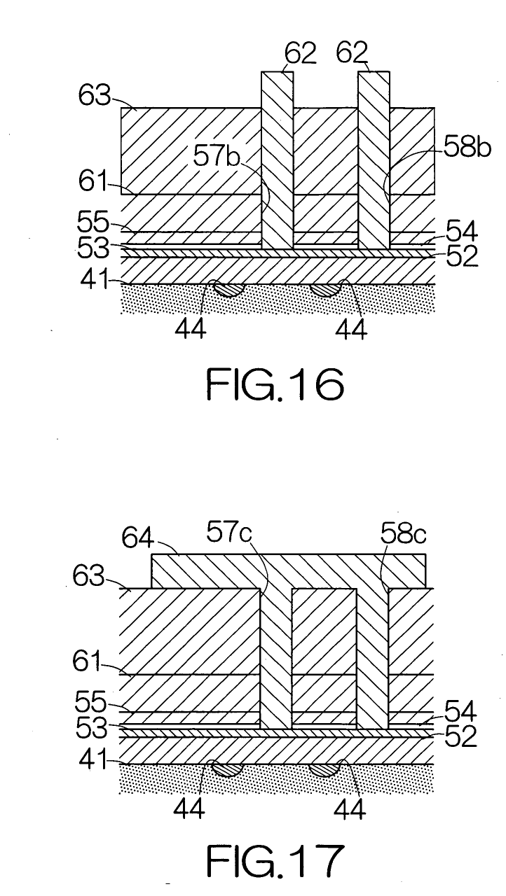

As shown in FIG. 16, a third Au layer 63 is formed on the second Au layer 61 after exposure and development of a photoresist 62. The photoresist 62 stands in grooves 57a, 58a formed in the second and first Au layers 61, 55 and the Ti layer 54. The thickness of the third Au layer 63 is set at 13 μm approximately, for example. Plating process is carried out to form the third Au layer 63. The thickness of the third Au layer 63 is set at 13 μm approximately, for example. The photoresist 62 is thereafter removed.

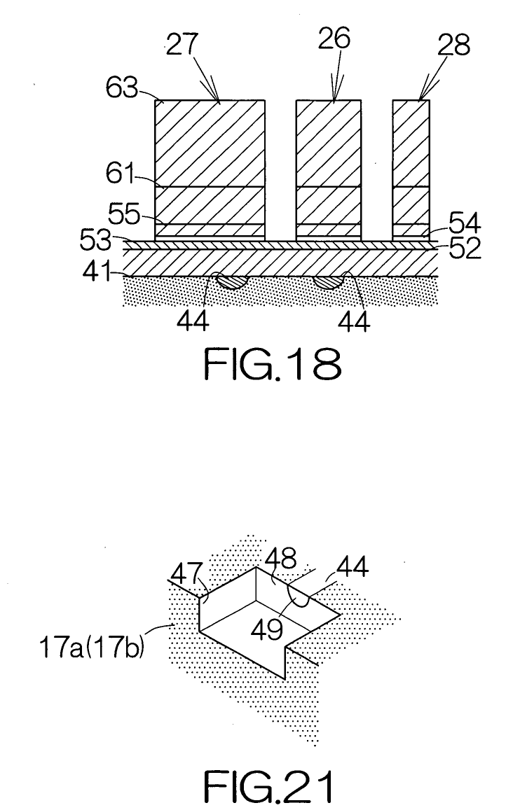

A photoresist 64 is subsequently applied to the surface of the wafer 41. The thickness of the photoresist 64 is set at 14 μm approximately, for example. The photoresist 64 is subjected to exposure and development. As a result, the photoresist 64 is formed in a predetermined pattern, as shown in FIG. 17. The photoresist 64 fills out grooves 57c, 58c formed in the third to first Au layers 63, 61, 55 and the Ti layer 54.

The third to first Au layers 63, 61, 55 and the Ti layer 54 are subsequently subjected to wet etching process based on the photoresist 64. Side surfaces of the first and second ground electrodes 27, 28 are thus formed. The photoresist 64 is thereafter removed. As shown in FIG. 18, the signal electrode 26 and the first and second ground electrodes 27, 28 are in this manner formed on the surface of the wafer 41.

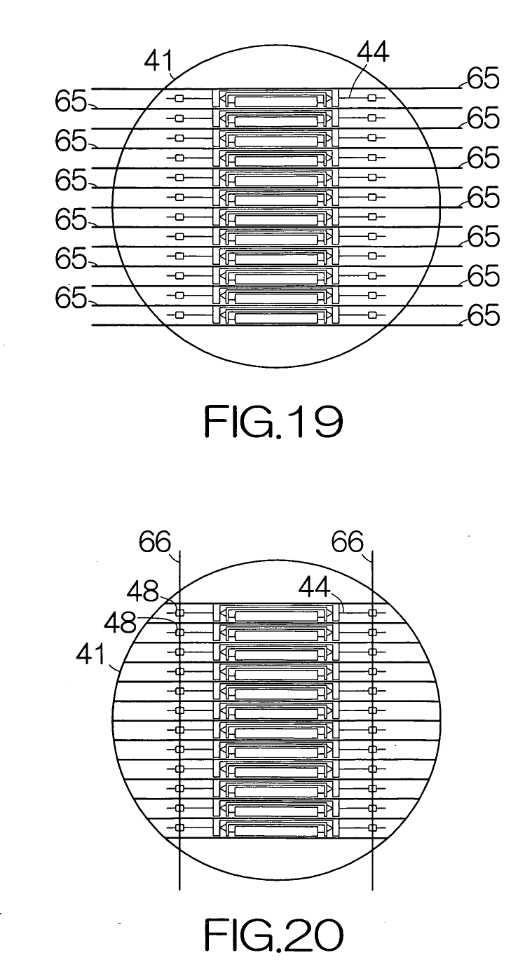

As shown in FIG. 19, the wafer 41 is subjected to cuts along parallel imaginary planes 65. The imaginary planes 65 are defined in parallel with the light waveguides 44. A metal blade may be utilized. The side surfaces of the optical chips 16 are thus formed.

As shown in FIG. 20, the wafer 41 is subsequently subjected to cuts along a pair of parallel imaginary plane 66, 66 defined in a space between the flat surfaces 48 opposed to each other within the groove 47, namely between the end surfaces 49 of the light waveguides 44. The imaginary planes 66 may be defined perpendicular to the light wave guides 44. A resin diamond blade may be utilized. As shown in FIG. 21, the end surfaces 17a, 17b of the individual optical chip 16 are thus formed.

A Si layer, not shown, is subsequently formed on the side surfaces of the individual optical chips 16. The thickness of the Si layer may be set at 100 nm approximately, for example. The flat surfaces 17a, 17b of the optical chip 16 are then subjected to AR (Anti-reflective) coating process. The optical chips 16 can be obtained in this manner.

The aforementioned method enables the cuts of the end surfaces 49 on the light waveguides 44 based on etching process such as reactive ion etching, for example. A smooth surface can be established at the tip end of the light waveguide 44 based on etching process.

In addition, the wafer 41 is divided into the optical chips 16 through the cuts along the imaginary planes 66 between the end surfaces 49, 49 of the light waveguides 44 within the groove 47. As a result, the tip end of the light waveguide 44 is reliably prevented from contact with the blade. Generation of cracks and scratches can reliably be prevented at the end surface 49 of the light waveguide 44. Moreover, the cuts can be effected in a shorter period. The working time can be shortened.

On the other hand, a protection member is adhered to the surface of the wafer along a straight line perpendicular to the light waveguides when the wafer is cut into the optical chips with the blade in a conventional method. The blade moves on the protection member. The protection member serves to prevent cracks at the front flat surfaces of the optical chips. However, the blade contacts with the tip end of the light waveguide at the cutting surface, so that scratches are formed on the cutting surfaces based on the friction between the blade and the tip ends of the light waveguides. A polishing or grinding process should subsequently be carried out on the cutting surfaces. Moreover, cracks happen in the cutting surfaces based on the stress from the blade. The cutting surface also suffers from pollution based on the adhesive of the protection member. Loss of light cannot be avoided at the end surfaces of the light waveguide.

The groove 47 may be formed after the formation of the Si layer 53 prior to the formation of the Ti layer 54 in the aforementioned method. Alternatively, the groove 47 may be formed after the formation of the signal electrode 26 and the first and second ground electrodes 27, 28 prior to the division of the wafer 41 into the optical chips 16.

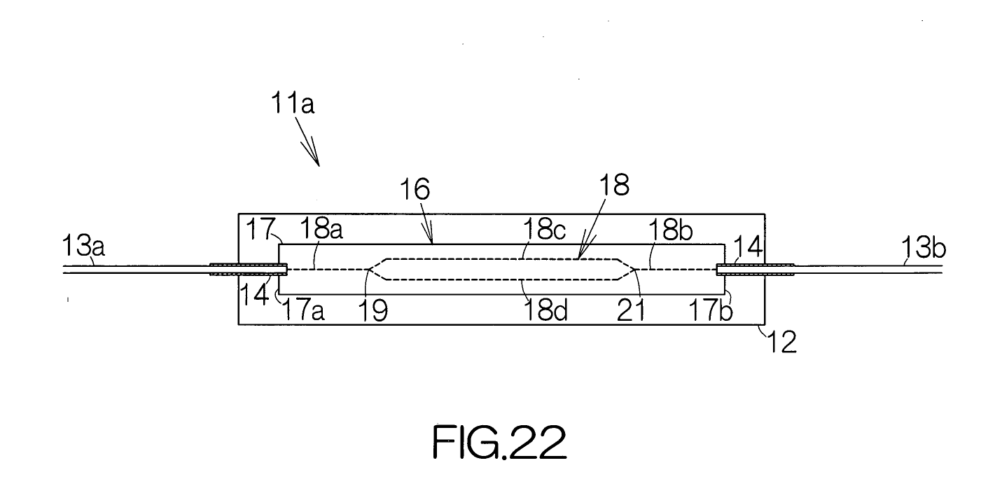

FIG. 22 schematically illustrates the structure of an optical modulator 11a according to a second embodiment of the present invention. This optical modulator 11a allows a direct attachment of the fiber optics 13a, 13b to the optical chip 16. Specifically, the tip end of the ferrule 14 is directly received on the optical chip 16 without any connector. The connectors 15, the lenses 22 and the photodiode 23 may be omitted from the optical modulator 11a.

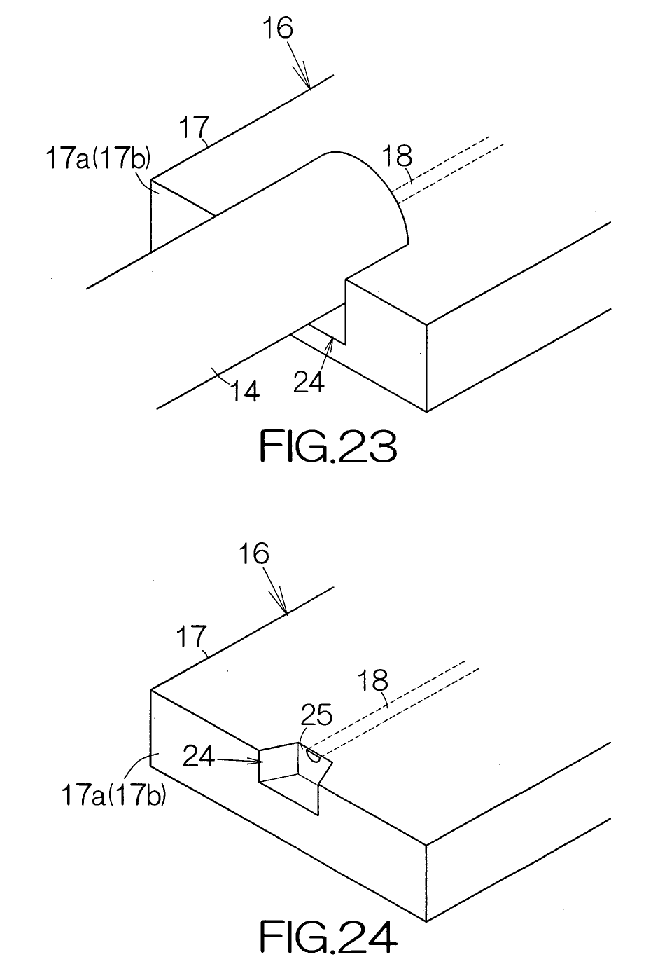

As shown in FIG. 23, the ferrule 14 is received in the depression 24 in the optical modulator 11a. The tip end of the fiber optics 13 may contact with the tip end of the light waveguide 18. The longitudinal axes of the fiber optics 13a, 13b are aligned with the centroid of the light waveguide 18. The aforementioned method may be utilized to form the optical chip 16 of the type. Like reference numerals are attached to structure or components equivalent to those of the aforementioned first embodiment.

The optical modulator 11a enables the reception of the ferrule 14 directly in the depression 24 of the optical chip 16. The depression 24 serves to position the fiber optics 13a, 13b relative to the light waveguide 18. As a result, the axis of the fiber optics 13a, 13b can easily be aligned with the centroid of the light waveguide 18. The alignment of the fiber optics 13a, 13b can be conducted within a shorter period. Moreover, loss of light is reliably prevented at the tip ends of the light waveguide in the manner as described above. As shown in FIG. 24, the depression 24 may be narrowed as it gets farther from the end surface 17a, 17b. The aforementioned method may be utilized to make the optical chip 16 of this type.

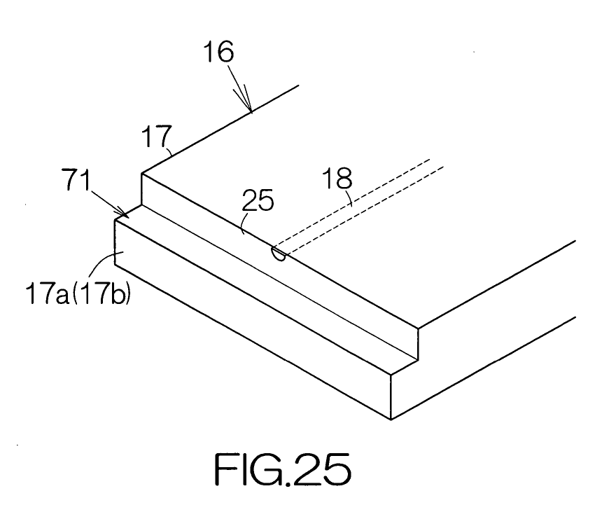

As shown in FIG. 25, a step 71 may be formed on the flat surface of the body 17 in place of the depression 24. The step 71 may extend in the direction perpendicular to the light waveguide 18 along the end surfaces 17a, 17b. The aforementioned method may be utilized to form the optical chip 16 of the type. The groove 47 may extend on the wafer 41 across the parallel light waveguides 44, for example, in the method.

1. An optical chip comprising:
a substrate made of a dielectric crystal and defining surfaces along imaginary parallel planes perpendicular to a flat surface of the substrate;
a light waveguide formed in the substrate along the flat surface of the substrate based on diffusion of a mineral material; and
a depression formed on the flat surface of the substrate so as to locate a tip end of the light waveguide at a position retreating from the plane.

2. The optical chip according to claim 1, wherein said depression includes a groove extending from the plane.

3. A method of making an optical chip, comprising:
diffusing a mineral material from a flat surface of a wafer made of a dielectric crystal so as to form a light waveguide extending in the wafer along the flat surface of the wafer; and
subjecting the flat surface of the wafer to etching process so as to form a surface along a reference plane perpendicular to the light waveguide.

4. The method according to claim 3, further comprising:
forming a groove crossing the light waveguide on the flat surface of the wafer so as to form the surface; and
cutting the wafer along an imaginary plane in a space defined between tip ends of the light waveguides opposed to each other in the groove.

5. An optical chip, comprising:
a substrate;
a light waveguide formed in the substrate; and
a depression formed on a surface of the substrate so as to locate a tip end of the light waveguide at a position retreating at least from an end surface of the substrate.

6. The optical chip according to claim 5, wherein the depression includes a groove extending from the end surface.

7. The optical chip according to claim 5, wherein the depression defines:
a first surface exposing the tip end of the light waveguide; and
second and third surfaces extending in a direction intersecting with the first surface, said second and third surfaces opposed to each other.

8. A method of making an optical chip, comprising:
forming a light waveguide in a wafer;
subjecting the wafer to etching process so as to form a dent in a predetermined area of the wafer, said predetermined area containing the light waveguide; and
cutting the wafer in a direction intersecting with the light waveguide within the dent.

9. The method according to claim 8, wherein the dent includes a groove extending in a direction intersecting with the light waveguide.

10. An optical modulator comprising:
a substrate defining a pair of end surfaces;
a light waveguide formed in the substrate;
a depression formed in the substrate so as to locate a tip end of the light waveguide at a position retreating at least from one of the end surfaces of the substrate; and
fiber optics received in the depression, said fiber optics having an end surface opposed to the tip end of the light waveguide.

11. The optical modulator according to claim 10, wherein a ferrule is attached to the tip end of the fiber optics.

12. A method of making an apparatus having a light waveguide, comprising:
forming a dent in a predetermined area of a substrate based on a chemical reaction, said predetermined area containing the light waveguide; and
cutting the substrate along an imaginary plane intersecting with an imaginary extension of the light waveguide within the dent.
